(19) United States
(12) Patent Application Publication
(10) Pub. No.: US 2026/0033628 A1
(43) Pub. Date: Feb. 5, 2026

(54) CABINET

(71) Applicant: Patriot Campers Holdings Pty Ltd, Molendinar, Queensland (AU)

(72) Inventors: Justin Montesalvo, Nerang, Queensland (AU); Harrison Bell, Molendinar, Queensland (AU)

(21) Appl. No.: 19/099,797

(22) PCT Filed: Aug. 4, 2023
(86) PCT No.: PCT/AU2023/050730

§ 371 Date: Jan. 30, 2025

(30) Foreign Application Priority Data
Oct. 31, 2022 (AU) 2022903224
Dec. 7, 2022 (AU) 2022283698

(51) Int. Cl. A47B 55/00

(52) U.S. Cl. CPC A47B 55/00

(57) ABSTRACT

Provided is a cabinet that includes an outer part for locating adjacent a body of the cabinet and at a corner of the cabinet. A gasket is provided for locating adjacent the body and for sealing the cabinet at the corner. The cabinet also includes an inner part for retaining the gasket. Advantageously, the gasket may seal the cabinet at the corner without the need for welding, and therefore the associated difficulty in material handling of the body during welding is avoided.

### TECHNICAL FIELD

The present invention relates to a cabinet. The present invention has particular, although not exclusive application to a cabinet for a camper trailer.

### BACKGROUND

The reference to any prior art in this specification is not, and should not be taken as an acknowledgement or any form of suggestion that the prior art forms part of the common general knowledge.

As part of the manufacturing process for camper trailers, storage cabinets are formed by welding metal sheets together. In practice, the metal sheets are unwieldy, complicating material handling during welding.

The preferred embodiment provides for improved manufacture of camper trailer storage cabinets.

### SUMMARY OF THE INVENTION

According to one aspect of the present invention, there is provided a cabinet including:
an outer part for locating adjacent a body of the cabinet and at a corner of the cabinet;
a gasket for locating adjacent the body and for sealing the cabinet at the corner; and
an inner part for retaining the gasket.

Advantageously, the gasket may seal the cabinet at the corner without the need for welding, and therefore the associated difficulty in material handling of the body during welding is avoided. Preferably, the cabinet is not welded at all.

The cabinet may further include a fastener for fastening the outer part, gasket and inner part together. The outer part, gasket and inner part may nest together. The fastening may be compression fastening. The fastener may include a threaded shaft and a nut. The nut may be located within the inner part. The outer part, gasket and inner part may be integrally formed, preferably by injection molding. Preferably, the seal is a waterproof or weatherproof seal.

The outer part may include a face plate. The face plate may be flush with the body. The outer part may be flush with the body. The outer part may include a receptacle for receiving the gasket. The outer part may include an alignment post extending from the face plate. The alignment post may be aligned along a gasket corner of the gasket. The outer part may define an aperture for receiving a fastener. The outer part may be rigid. The perimeter of outer part may engage with the perimeter of the body. The perimeters may be co-incident with the gasket.

The gasket may seal the interface between the body and the outer part. Preferably, the gasket is located inside the cabinet. The gasket may be resilient. The gasket may be compressible. The gasket may include rubber. The gasket may define an aperture for receiving a fastener. The gasket may define a gasket corner along which an alignment post of the outer part may be aligned. The gasket may include a socket for receiving a plug of the inner part. The socket may be L-shaped. The gasket may define a plug for being received in at least one socket of the body. The plug may be L-shaped. The gasket may define a receptacle for receiving the body.

The gasket may be held or compressed within the body using a tapering arrangement. The inner part may include a receptacle for receiving the gasket. The inner part may define a plug for being received in a socket of the gasket. The plug may be L-shaped. The inner part may be rigid.

The body may include at least one socket for receiving the gasket. The body may include a lip for being received in the gasket. The body may include two side panels interconnecting a top and a bottom panel. The body may further include an end panel. The panels may be adhered or mechanically fastened together. The body may include a door.

According to another aspect of the present invention, there is provided a corner seal for a cabinet, the corner seal including:
an exposed part for locating at a corner of the cabinet;
a gasket for sealing the cabinet at the corner; and
a retainer for retaining the gasket.

According to another aspect of the present invention, there is provided a method for forming a cabinet including:
locating an outer part adjacent a body of the cabinet and at a corner of the cabinet;
locating a gasket adjacent the body to seal the cabinet at the corner; and
retaining the gasket using an inner part.

The outer part may be located to fill a gap defined by the body. The gasket may receive the body and/or abut the outer part. The gasket may plug the body. The inner part receives and/or abuts the gasket. The inner part may plug the gasket. The inner part may expand the gasket.

The method may involve fastening the outer part, gasket and inner part together with a fastener. The fastening may involve compression fastening.

Any of the features described herein can be combined in any combination with any one or more of the other features described herein within the scope of the invention.

### BRIEF DESCRIPTION OF THE DRAWINGS

Preferred features, embodiments and variations of the invention may be discerned from the following Detailed Description which provides sufficient information for those skilled in the art to perform the invention. The Detailed Description is not to be regarded as limiting the scope of the preceding Summary of the Invention in any way. The Detailed Description will make reference to a number of drawings as follows:

FIG. 1A is an upper front perspective view of a camper trailer storage cabinet in accordance with an embodiment of the present invention;

FIG. 1B is an upper front perspective view of the cabinet of FIG. 1A showing an exploded corner seal.

FIG. 2A is a lower front perspective view of the cabinet of FIG. 1A;

FIG. 2B is a close-up lower front perspective view of the detail Y in FIG. 2A

FIG. 3A is an upper front perspective view of the exploded corner seal shown in FIG. 1B;

FIG. 3B is a lower rear perspective view of the exploded corner seal of FIG. 3A;

FIG. 4A is an upper front perspective view of the assembled corner seal shown in FIG. 3A;

FIG. 4B is a lower front perspective view of the assembled corner seal shown in FIG. 3A;

FIG. 4C is an upper rear perspective view of the assembled corner seal shown in FIG. 3B;

FIG. 4D is a lower rear perspective view of the assembled corner seal shown in FIG. 3B;

FIG. 5 is an orthographic drawing showing various views of the assembled corner seal in FIG. 4A;

FIG. 6A is an upper front perspective view of the cabinet of FIG. 1A showing hidden detail of the corner seal;

FIG. 6B is a close-up upper front perspective view of the detail Z in FIG. 6A

FIG. 7 is an exploded upper front perspective view of a body of the cabinet of FIG. 1A;

FIG. 8A is an exploded side sectional view of the base of the cabinet of FIG. 1A; and

FIG. 8B is an assembled side sectional view of the base of the cabinet of FIG. 8A.

### DETAILED DESCRIPTION OF PREFERRED EMBODIMENTS

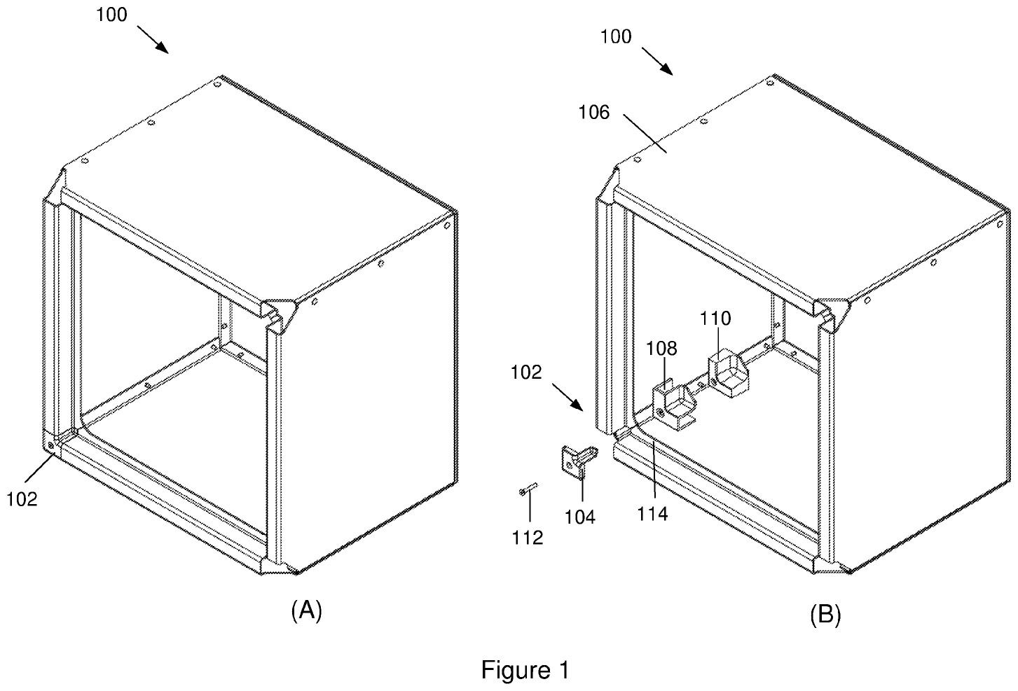

According to and embodiment of the present invention, there is provided a camper trailer storage cabinet 100 with a corner seal 102 as shown in FIG. 1A.

As can best be seen in FIG. 1B, the corner seal 102 includes an outer facial part 104 for locating adjacent a box-like body 106 of the cabinet 100 and at a lower front corner of the cabinet 100. A resilient rubber gasket 108 is located adjacent the body 104, inside of the cabinet 100, to seal the cabinet 100 at the corner. The corner seal 102 also includes an inner retainer part 110 for retaining the gasket 108. The cabinet 100 further includes a fastener 112 for compression fastening the nesting outer part 104, gasket 108 and inner part 110 together.

Advantageously, the gasket 108 seals the cabinet 100 at the corner without the need for welding, and therefore the associated difficulty in material handling of the body 106 during welding is avoided. Indeed, the cabinet 100 is not welded at all thereby greatly assisting with material handling and manufacture. The body 106 defines an endless jamb 114 (or lip) received within the corner seal 102, and against which a front door (not shown) abuts.

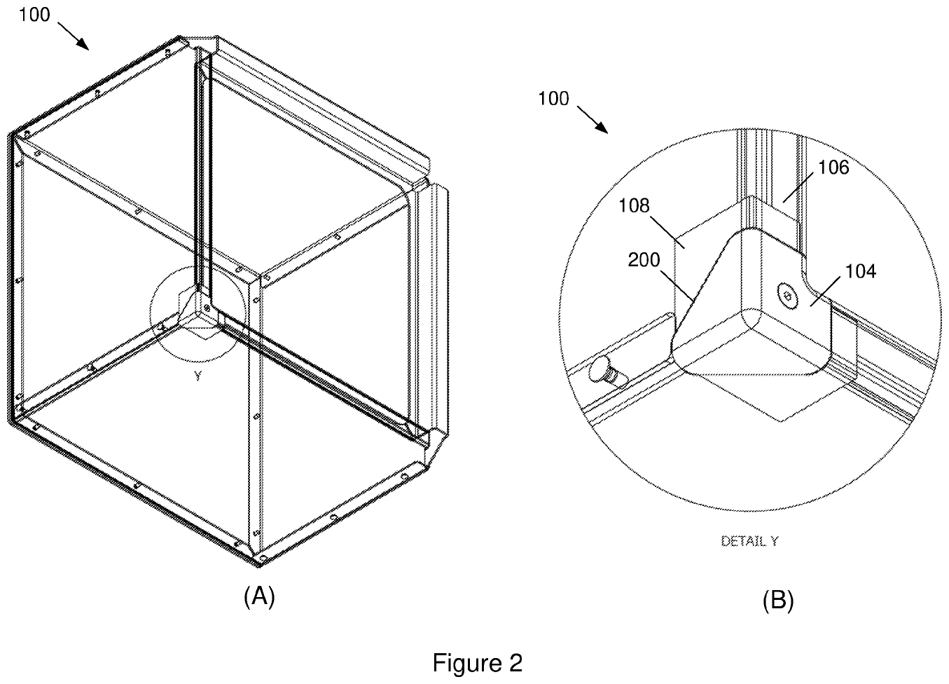

As can best be seen in FIG. 2, the exposed perimeter of outer part 104 engages with the complementarily-shaped perimeter of the corner of the body 106. The outer part 104 is flush with and matches the body 106. The underlying gasket 108 seals this perimeter interface 200 (or gap) between the fitted body 106 and the outer part 104. In particular, the exposed interface 200 lies co-incident with the underlying gasket 108 pressed against it.

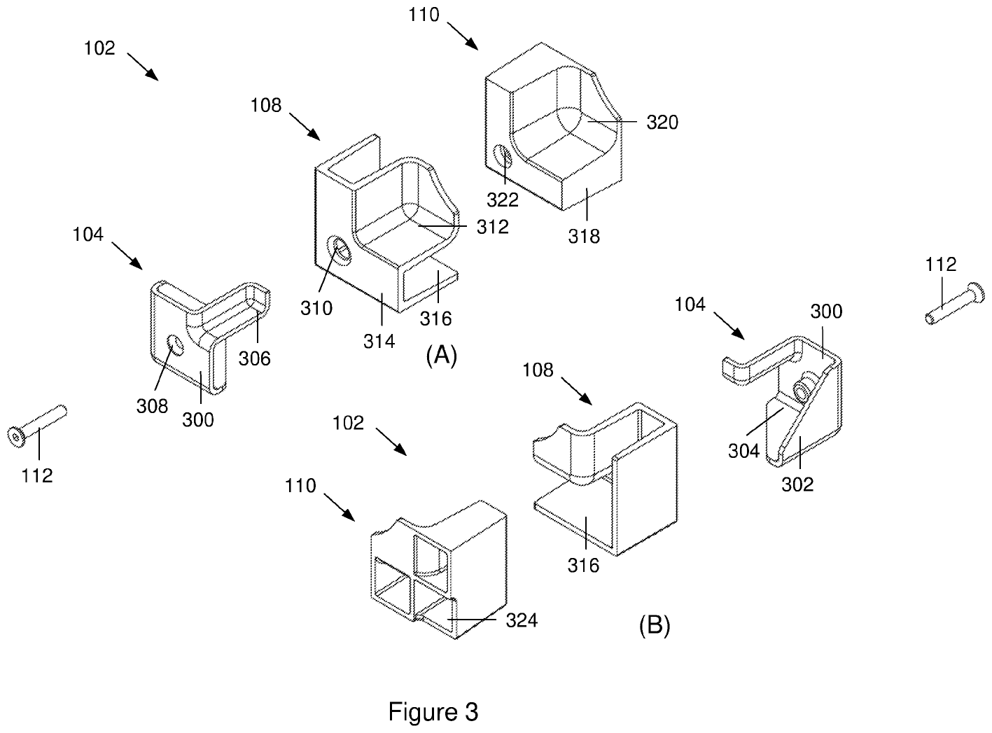

As can best be seen in FIG. 3, the exposed outer part 104 includes a face plate 300 which sits flush with the body 106. An L-shaped flange 302 extends from the face plate 300 and forms a receptacle 304 for receiving the oversized gasket 108. The outer part 104 also includes an alignment post 306 extending from the face plate 300. The alignment post 306 is aligned along a gasket corner of the gasket 108. The outer part 104 also defines a countersunk aperture 308 for receiving the fastener 112.

The gasket 108 similarly defines an aperture 310 for receiving the fastener 112. Further, the gasket 108 defines the gasket corner along which the alignment post 306 of the outer part 104 is aligned. The gasket 108 defines an upper receptacle 312 for receiving the alignment post 306 and cabinet body jamb 114.

The oversized gasket 108 defines a L-shaped plug 314 for being received in channel sockets of the body 106. On the reverse side, the gasket 108 also defines a L-shaped socket 316 for receiving a L-shaped plug 318 of the inner part 110. The inner part plug 318 is tapered to expand the plug 314 of the gasket 108 within the sockets of the body 106 to form a tight fit.

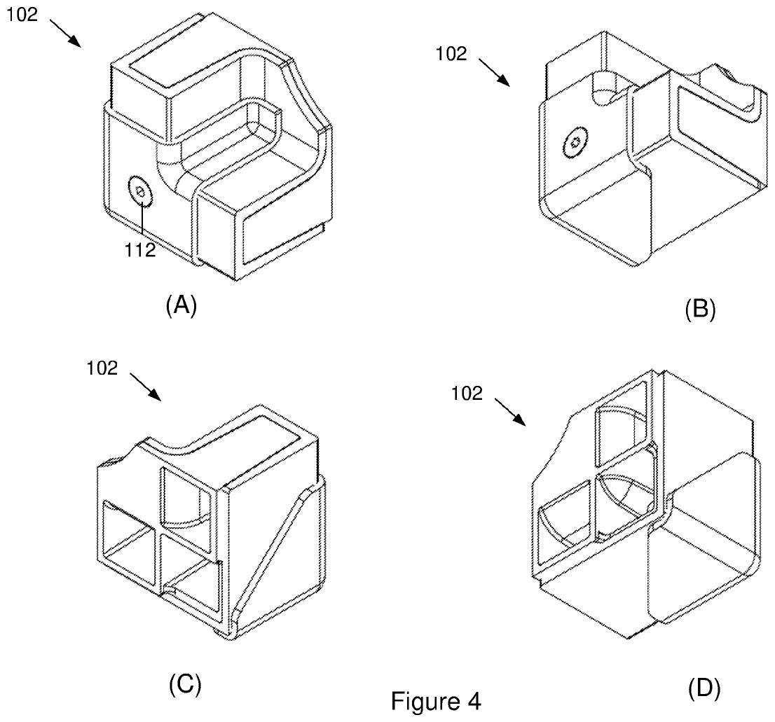

The inner part 110 includes a receptacle 320 for receiving the gasket 108. The inner part 110 defines an aperture 322 for receiving the fastener 112. On the reverse side, the inner part 110 defines a recess 324 for receiving a nut of the fastener 112. The fastener 112 is used to compress the gasket 108 between the outer part 104 and the inner part 110 as shown in FIG. 4.

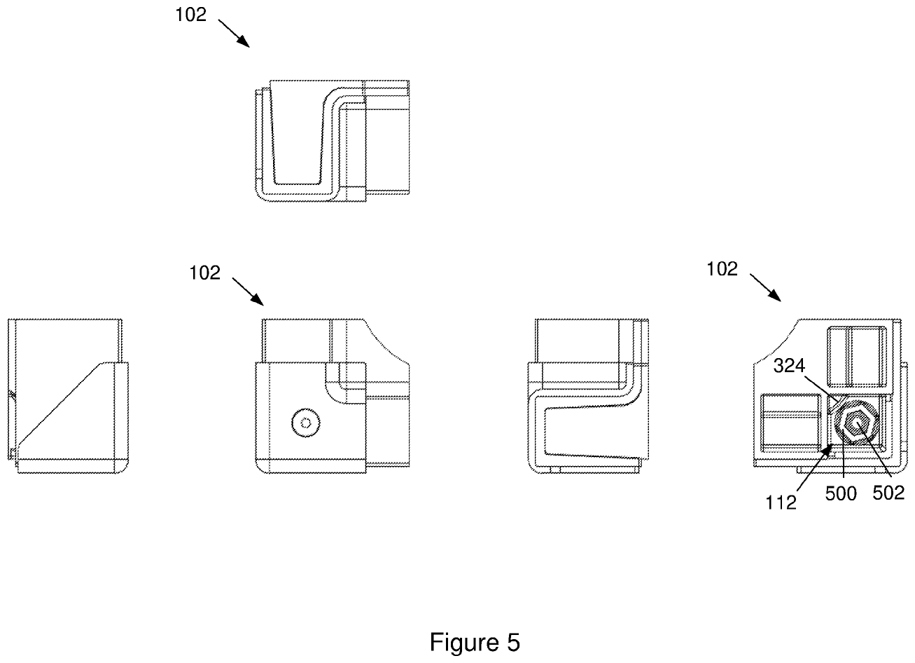

As can best be seen in FIG. 5, the fastener nut 500 in the recess 324 engages with a threaded shaft 502 of the fastener 112 to pull and hold the seal 102 together. In particular, the fastener 112 includes an M6 countersunk bolt 502 and a zinc nyloc nut 500 captured into the back of the inner part 110.

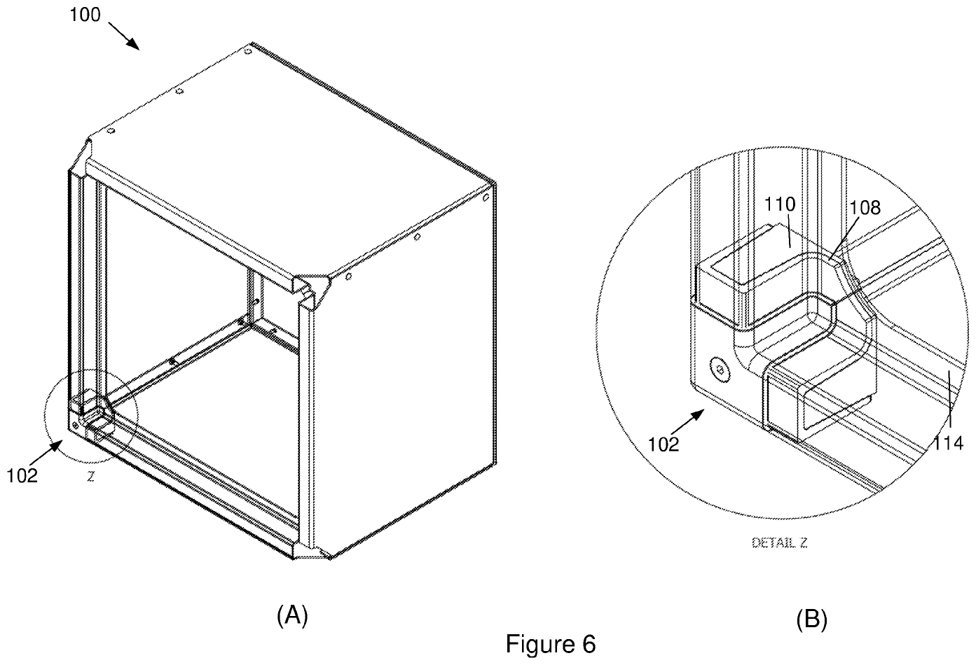

Turing to FIG. 6, the seal 102 seals the corner of the cabinet 100. The inner part 110 pushes and retains the gasket 108 against the lip jamb 114 as the fastener 112 is tightened.

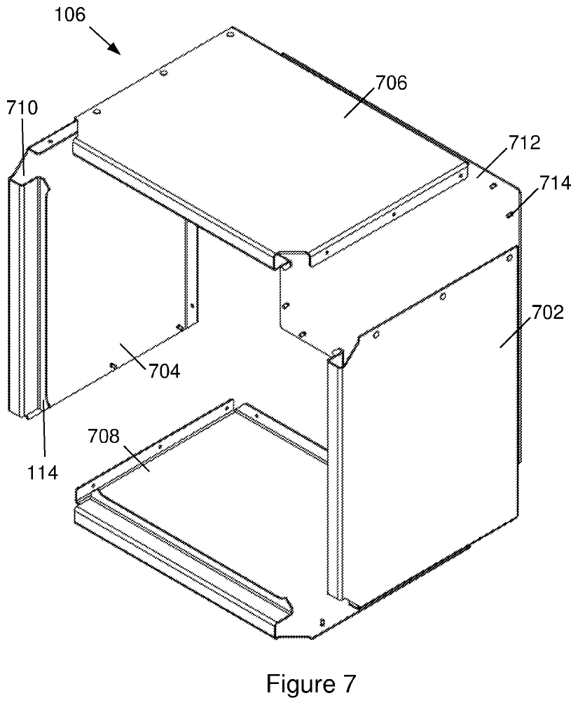

Turing to FIG. 7, the body 106 includes two side panels 702, 704 interconnecting a top panel 706 and a bottom panel 708. The front of each sheet metal panel 702, 704, 706, 708 is folded to define the lip jamb 114, and the channel sockets 710 in which the L-shaped plug 314 of the gasket 108 is compressed. In this manner, each front corner of the cabinet 100 is fitted with a seal 102. The body 106 is fitted with a door abutting the lip jamb 114. In practice, the door is exposed to the elements, and the front of the cabinet 100 is sealed to the ingress of rain by virtue of the waterproof or weatherproof seals 102.

The body 106 further includes an end panel 712. Whilst the panels 702, 704, 706, 708, 712 can be mechanically fastened together with rivets or screws 714, they may additionally or alternatively be adhered together for improved resistance to the ingress of water. The body 106 is sealed with an adhesive silicon along a folded tab on the flat of the tab and the outside along the exposed seam to finish.

The rigid outer part 104, compressible gasket 108 and rigid inner part 110 are integrally formed, preferably by injection molding. The outer part 104 and rigid inner part 110 are formed from Black Nylon GF30, whereas the rubberised gasket 108 is formed from a Shore A 30 material.

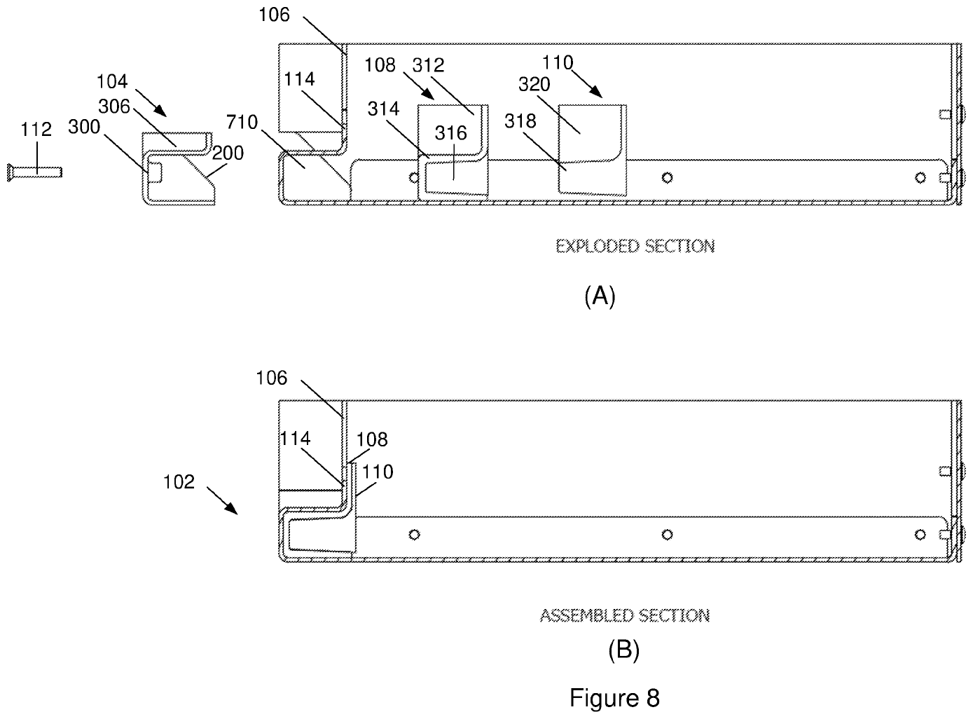

A method for forming the cabinet 100 is briefly described with reference to FIG. 8.

First, the box-like body 106 of the cabinet 100 is assembled.

The outer part 104 is located adjacent the body 106 at a corner of the cabinet 100. The outer part 104 is located to fill a gap defined by the body 106 at the perimeter interface 200.

The internal gasket 108 is located adjacent the body 108 to seal the cabinet 100 at the corner. The L-shaped plug 314 of the gasket 108 is received in the channel sockets 710. The gasket 108 receives the lip jamb 114 of the body 106 in receptacle 312. The gasket 108 also abuts the face plate 300 and alignment post 306 of the outer part 104.

The L-shaped plug 318 of the inner part 110 plugs the L-shaped socket 316 of the gasket 108. The receptacle 320 of the inner part 110 receives and abuts the rear of the gasket 108. The tapered inner part 110 expands the gasket 108 to be retained in the channel sockets 710.

The method then involves compression fastening the outer part 104, gasket 108 and inner part 110 together with the fastener 112.

The other three seals 102 can then be assembled in a similar manner.

Finally, the door is hinged to the front of the cabinet 100. The cabinet 100 can be made with an internal flush style door or an external door going over the door jamb profile.

A person skilled in the art will appreciate that many embodiments and variations can be made without departing from the ambit of the present invention.

In one embodiment, the cabinet 100 may be an electrical cabinet or other like cabinet exposed to the elements.

In one embodiment, the fastener 112 is not required.

The body panels 702, 704, 706, 708, 712 may be formed of aluminium or steel or any specific material.

In compliance with the statute, the invention has been described in language more or less specific to structural or methodical features. It is to be understood that the invention is not limited to specific features shown or described since the means herein described comprises preferred forms of putting the invention into effect.

Reference throughout this specification to ‘one embodiment’ or ‘an embodiment’ means that a particular feature, structure, or characteristic described in connection with the embodiment is included in at least one embodiment of the present invention. Thus, the appearance of the phrases ‘in one embodiment’ or ‘in an embodiment’ in various places throughout this specification are not necessarily all referring to the same embodiment. Furthermore, the particular features, structures, or characteristics may be combined in any suitable manner in one or more combinations.

1. A cabinet including:
an outer part for locating adjacent a body of the cabinet and at a corner of the cabinet;
a gasket for locating adjacent the body and for sealing the cabinet at the corner; and
an inner part for retaining the gasket.

2. The cabinet as claimed in claim 1, wherein:
the gasket seals the cabinet at the corner without the need for welding, and therefore the associated difficulty in material handling of the body during welding is avoided; and/or
the cabinet is not welded at all.

3. The cabinet as claimed in claim 1, further including a fastener for compression fastening the outer part, gasket and inner part together.

4. The cabinet as claimed in claim 1, wherein the outer part, gasket and inner part nest together.

5. The cabinet as claimed in claim 1, wherein the outer part is rigid and flush with the body.

6. The cabinet as claimed in claim 1, wherein the perimeter of outer part engages with, or is adjacent to, the perimeter of the body.

7. The cabinet as claimed in claim 1, wherein the perimeters are co-incident with the gasket.

8. The cabinet as claimed in claim 1, wherein the gasket weatherproof seals the interface between the body and the outer part.

9. The cabinet as claimed in claim 1, wherein the gasket is resilient and located inside the cabinet.

10. The cabinet as claimed in claim 1, wherein the gasket includes a socket for receiving a plug of the inner part.

11. The cabinet as claimed in claim 1, wherein the gasket defines a plug for being received in at least one socket of the body.

12. The cabinet as claimed in claim 1, wherein the gasket is held or compressed within the body using a tapering arrangement.

13. The cabinet as claimed in claim 1, wherein the inner part defines a plug for being received in a socket of the gasket.

14. The cabinet as claimed in claim 1, wherein the body includes at least one socket for receiving the gasket.

15. The cabinet as claimed in claim 1, wherein the body includes two side panels interconnecting a top and a bottom panel, the panels being adhered or mechanically fastened together.

16. A corner seal for a cabinet, the corner seal including:
an exposed part for locating at a corner of the cabinet;
a gasket for sealing the cabinet at the corner; and
a retainer for retaining the gasket.

17. A method for forming a cabinet including:
locating an outer part adjacent a body of the cabinet and at a corner of the cabinet;
locating a gasket adjacent the body to seal the cabinet at the corner; and
retaining the gasket using an inner part.

18. The method as claimed in claim 17, wherein the outer part is located to fill a gap defined by the body.

19. The method as claimed in claim 17, wherein the gasket:
receives the body;
abuts the outer part; and/or
plugs the body.

20. The method as claimed in claim 17, wherein the inner part:
receives the gasket;
abuts the gasket;
plugs the gasket; and/or
expands the gasket.

21. (canceled)
